(19) United States
(12) Patent Application Publication
(10) Pub. No.: US 2004/0264139 A1
(43) Pub. Date: Dec. 30, 2004

(54) Process for manufacturing a cover

(75) Inventors: Kenichi Hashizume, Gunma (JP); Takaharu Fujii, Kanagawa (JP)

Correspondence Address: HARRINGTON & SMITH, LLP, 4 RESEARCH DRIVE, SHELTON, CT, 06484-6212, US

(73) Assignee: NOKIA CORPORATION

(21) Appl. No.: 10/603,913

(22) Filed: Jun. 24, 2003

(51) Int. Cl. H05K 7/20

(52) U.S. Cl. 361/715

(57) ABSTRACT

A process of manufacturing a cover for an electronic device, the process comprising forming the cover for the device, incorporating electrical circuitry into the cover during the formation, and providing on the cover an integral connector structure for connecting the electrical circuitry to an electronic component.

This invention relates to processes for manufacturing covers for electronic devices. This invention also relates to covers for electronic devices. More particularly, but not exclusively, the invention relates to processes for manufacturing covers for mobile phones, and also to the covers for the mobile phones.

The density of component packaging in mobile phones is increasing with a tendency to include a greater number of features in the phones, for example cameras and input devices. The high density packaging also makes the assembling process more complicated.

According to one aspect of this invention there is provided a process of manufacturing a cover for an electronic device, the process comprising forming the cover for the device, incorporating electrical circuitry into the cover during the formation, and providing on the cover an integral connector structure for connecting the electrical circuitry to an electronic component.

According to another aspect of this invention, there is provided a cover for an electronic device, the cover comprising an integral electrical circuitry, and an integral connector structure on the cover for connecting the electrical circuitry to an electronic component.

Embodiments of the invention will now be described by way of example only, with reference to the accompanying drawings, in which:—

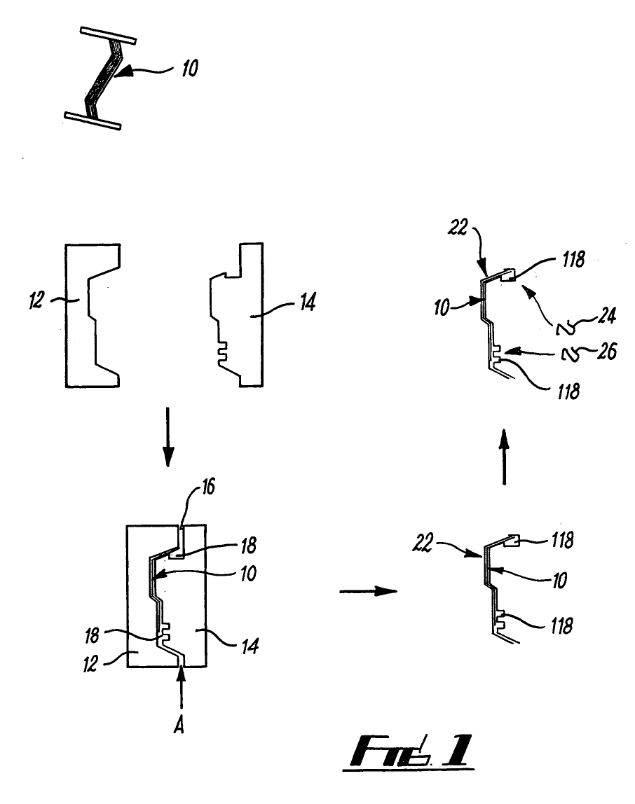

FIG. 1 is a schematic diagram of a first method of forming a cover for an electronic device;

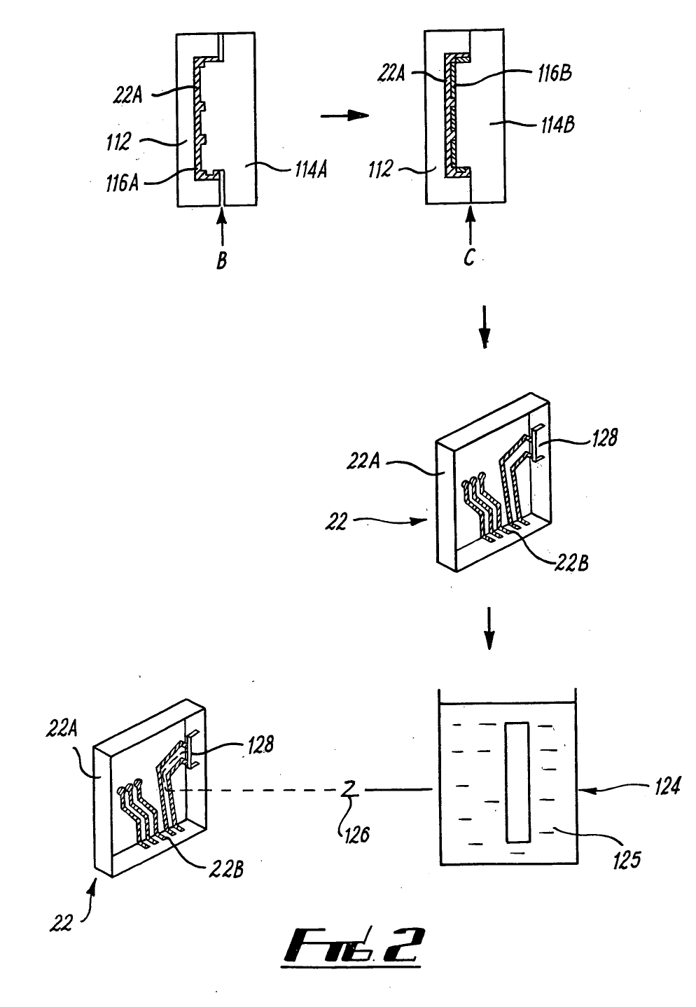

FIG. 2 is a schematic diagram of a second method of forming a cover for an electronic device;

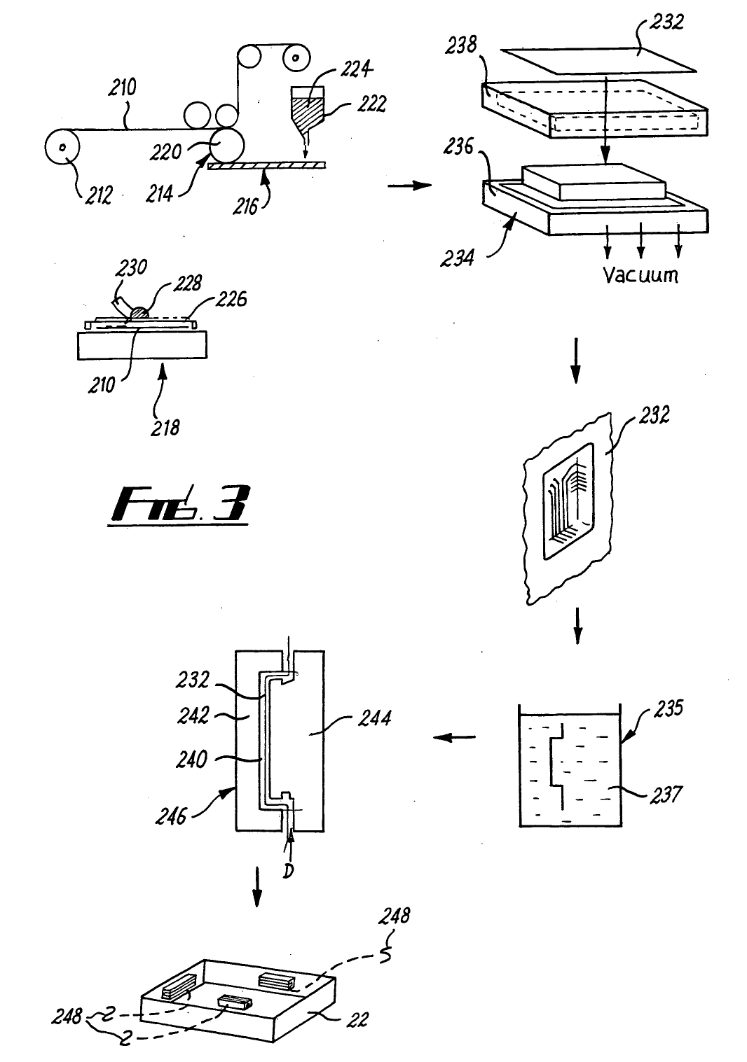

FIG. 3 is a schematic diagram of a third method of forming a cover for an electronic device;

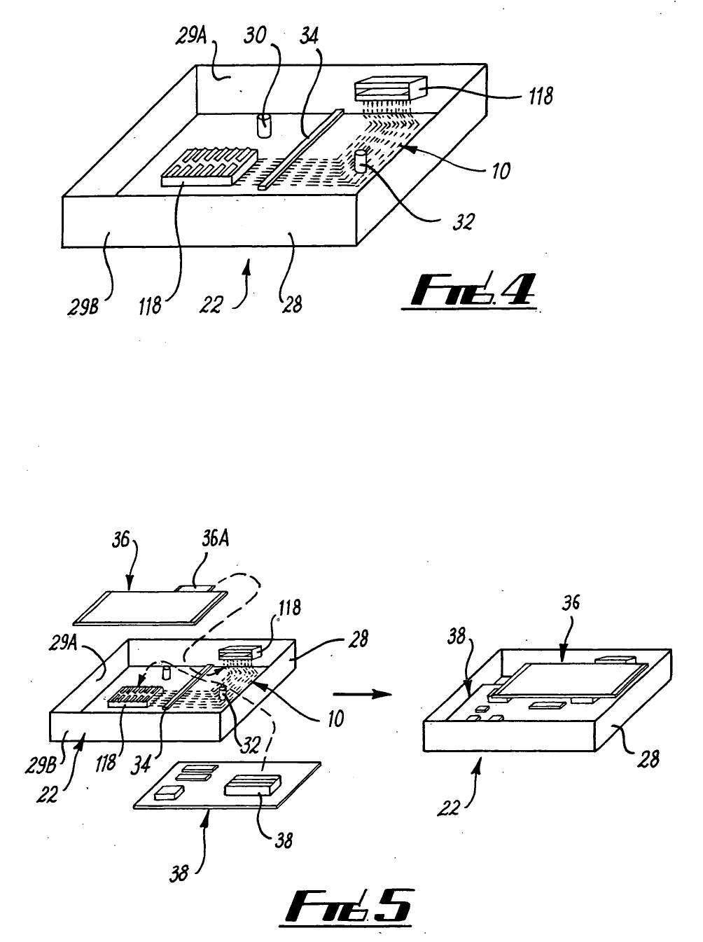

FIG. 4 is a diagrammatic perspective view of a cover made using the methods according to FIGS. 1, 2 or 3;

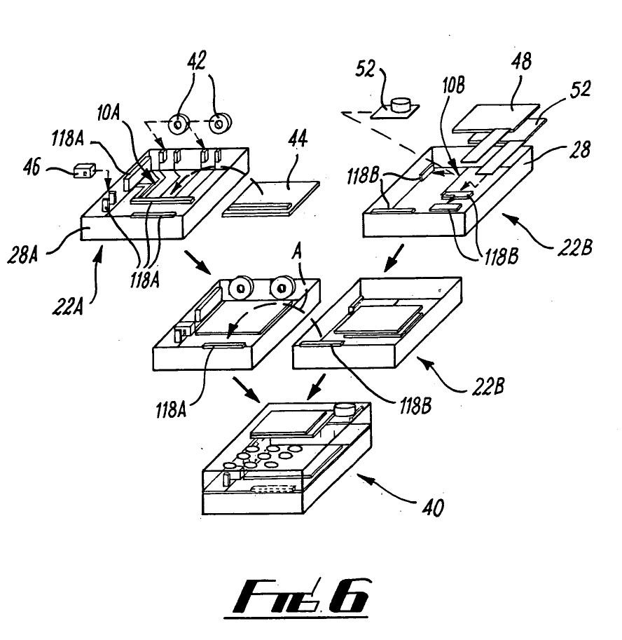

FIG. 5 is a diagrammatic representation of the assembly of component parts into the cover arrangement shown in FIG. 2; and

FIG. 6 is a schematic diagram of a method of assembling an electronic device comprising covers made according to the invention.

Referring to FIG. 1, there is shown a schematic diagram representing the steps of a first method in the manufacture of a cover 22 for an electronic device, for example a mobile radio terminal, such as a mobile phone.

The first step referred to in FIG. 1 is the formation of an electrical circuitry element 10, in the form of a stamped metal sheet, by suitable means known in the art. The circuitry element 10 is arranged between two mould parts 12, 14 in a moulding space 16. A plastics material is injected into the moulding space as indicated by the arrow A. The plastics material may be, for example, acrylonitrile-butadiene-styrene alloy (PL-ABS), a polycarbonate (PC), a polystyrene (PS), polymethylmethacrylate (PMMA), another acryl resin, polyphthalamide (PPA), polybutyleneterephthalate (PBT), an olefin polymer such as polypropylene (PP). The moulding space 16 comprises regions for the moulding of integral connector structures, and these are designated 18.

After the plastics material has set, the mould parts 12, 14 are removed to provide the moulded cover 22. The moulded cover 22 incorporates the electrical circuitry element 10 and includes connector structures 118 which correspond to the regions 18 in the moulding space 16.

Holding members 24, 26 are then arranged in the connecting structures 118 to hold electronic components in the connecting structures 118. The holding members 24, 26 are, in this example, in the form of springs and resiliently engage the components inserted into the connector structures 118.

FIG. 2 shows a schematic diagram of a second method for the manufacture of a cover 22 for an electronic device, for example a mobile radio terminal, such as a mobile phone.

In this embodiment, first and second mould parts 112, 114 are brought together to provide a moulding space 116. A plastics material, for example as set out in the above list is injected into the moulding space 116 as represented by the arrow B to form a first part 22A of the eventual cover 22. The second mould part 114A is then removed and replaced by a third mould part 114B to define a moulding space 116B between the first part 22A and the third mould part 114B. The moulding space 116B includes a line pattern thereon to form the region which eventually provides the electrical circuitry. A further plastics material is injected into the moulding space 116B, as represented by the arrow C, and this plastics material can be any suitable plastic material, and can be for example, one as described above. The further plastics material incorporate a seeding substance for allowing metal plating onto the plastics material forming the second part 22B. The seeding substance can be in the form of metal particles.

After the second plastics material is injected, as shown by the arrow C, and allowed to cool, the cover 22 is removed is removed from the mould and thereafter metalisation takes place in a plating bath 124, which contains a plating solution 125 The metalisation can be in the form of electrolytic plating, electroless plating, or both electrolytic and electroless. During this metalisation process, metal is deposited onto the lines forming the line pattern of the second part 22B of the cover to form the electrical circuitry. Finally, holding members in the form of contact springs 126, which are inserted into respective connector structures 128 moulded into the cover 22.

A third method of forming the cover 22 is shown in FIG. 3, in which a substrate, in the form of a sheet of a plastics material 210 is fed from a roll 212 to a printing arrangement 214. The printing arrangement can be an offset printing arrangement 216, or a screen printing arrangement 218. The offset printing arrangement 216 comprises a printing roller 220 and a cartridge 222 containing ink 224. The ink 224 contains a seeding substance in the form of metal particles to form a precursor of the electrical circuitry on the sheet 210. The ink 224 is printed onto the plastic sheet 210 in a line pattern corresponding to the connector line of the electrical circuitry.

The plastic sheet 210 can be any suitable film of plastics material, for example polyethylene, polypropylene, polystyrene, acrylonitrile-butadiene-styrene, acrylic resin, polyamides, polycarbonates, polybutylene terephthalate, polyethylene terphthalate, polyphenylene sulphide, thermoplastic polyurathene, derivatives of the above polymers.

As an alternative to offset printing apparatus 216, screen printing apparatus 218 can be used which comprises a screen mask 226, an ink cartridge 228 and a wiper in the form of a squeegee 230.

In the case of the offset printing apparatus 216 and the screen printing apparatus 218, the pattern printed on the sheet is a line pattern which is a precursor for the electrical circuitry to be applied to the cover 22.

After the sheet material is printed, it is then cut to discreet elements 232 which are arranged in a press mould apparatus 234, which comprises two tooling parts 236, 238 and the element 232 is then press formed into the desired shape, which will be the shape of the cover 22 to be formed. The apparatus 234 can be a vacuum press, a vacuum/heat press or a heat press.

After the pressing operation described above, the moulded element 232 is then arranged in a moulding space 240 between two moulding parts 242, 244 of an injection mould 246. A plastics material, such as the material described above is then injected as shown by the arrow D to form the cover 22. The electrical circuitry element is provided within the body of the cover 22. After the formation of the cover 22 contact springs 248 are inserted into the connecting structures 118 formed during the injection moulding step.

After the element 232 has been vacuumed formed, it then undergoes metalisation by plating in a plating bath 235 holding a plating solution 237. The plating bath 235 can be an eletrolytic plating bath, or an electroless plating bath. Alternatively, the metalisation step could involve two steps, one being an electroless plating step and the other being a plating step, in which case two baths 235 are required. The plating step plates the lines of the pattern on the element 232 with metallic material to form the electrical circuitry.

Referring to FIG. 2, there is shown a cover 22 formed by the method described above. The cover 22 comprises a body 28 having an inner surface 29A and an outer surface 29B. The body 28 is formed from a suitable plastics material, for example acrylonitrile-butadiene-styrene alloy (PL-ABS), polycarbonate (PC), polystyrene (PS), polymethylmethacrylate (PMMA), other acryl resins, polyphthalamide (PPA), polybutyleneterephthalate (PBT), olefin polymers such as polypropylene (PP) and has incorporated therein the electrical circuitry element 10 between the inner and outer surfaces 29A, 29B. The circuitry element 10 is shown in broken lines to represent that it is moulded within the plastics material of the cover 22.

As can be seen, the body 28 also includes other features such as bosses 30, 32 and a rib 34.

FIG. 3 is a schematic representation of the assembly of electronic components 36, 38 into the cover 22. The components 36, 38 are suitable components for use in a mobile phone, and the person skilled in the art would immediately realise the types of components that would be suitable. The component 36 comprises a first connecting member 36A for insertion into one of the connecting structure 118. The second component 38 comprises a second connecting member 38A for insertion into the other of the connecting structures 118.

On the right hand side of FIG. 3, there is shown the cover 22 having the electronic components 36, 38 assembled therein.

Referring to FIG. 4, there is shown schematically the assembly of electronic components into the covers which form a mobile phone which is diagrammatically represented in FIG. 4 and is designated with the numeral 40.

The two covers are designated respectively 22A and 22B. The first cover 22A represents the rear housing the mobile phone, and includes an electronic circuitry element 10A. Also, there are provided a plurality of connecting structures 118A.

Suitable electronic components, for example in the form of speakers 42, a main circuit board 44, and an alternating cover or AL are arranged in connection with the respective connecting structures 118A.

The second cover arrangement 22B represents the front housing of the mobile phone, and includes an electrical circuitry element 10B, manufactured in the same way as described above. The appropriate electronic components, for example a display board 48, a touch panel 50, and a camera 52 are connected with appropriate connecting structures 118B in the second cover arrangement 22B.

When the components have been assembled into the respective covers 22A, 22B, the second step in the process is to connect the front and rear covers 22A, 22B together. For this purpose, a respective one of the connectors 118A and 118B on the covers 22A, 22B are provided to allow electrical connection between the first and second covers 22A, 22B. The arrow A shows the connection together of these two connecting structures 118A, 118B to provide the electrical connection between the front and rear covers 22A, 22B.

The third step in the process shows the mobile phone 40 assembled together.

There is thus described, in the preferred embodiment, a cover for a mobile phone, and a process for forming a cover for a mobile phone, which have the advantage of allowing easy assembly of the electronic components into the cover. In addition, the provision of an integral connector structure on the cover member has the advantage of increasing the amount of space inside the mobile phone for the components.

Various modifications can be made without departing from the scope of the invention, for example, the connecting structures 118 can be of any suitable size, shape or position in the cover 22.

Whilst endeavouring in the foregoing specification to draw attention to those features of the invention believed to be of particular importance it should be understood that the Applicant claims protection in respect of any patentable feature or combination of features hereinbefore referred to and/or shown in the drawings whether or not particular emphasis has been placed thereon.

1. A process of manufacturing a cover for an electronic device, the process comprising forming the cover member for the device, incorporating electrical circuitry into the cover during the formation, and providing on the cover an integral connector structure for connecting the electrical circuitry to an electronic component.

2. A process according to claim 1, wherein the step of incorporating the electrical circuitry into the cover comprises forming an electrical circuitry element, arranging the electrical circuitry element in a mould and moulding the cover onto the electrical circuitry element.

3. A process according to claim 2, wherein the moulding of the cover comprises introducing a plastics material into the mould after the electrical circuitry element is arranged in the mould, and forming the connector structure with the cover in the mould.

4. A process according to claim 3, wherein the plastics material is introduced into the mould by injection.

5. A process according to claim 1, wherein the step of incorporating the electrical circuitry into the cover comprises forming a first part of the cover in a first moulding operation, and forming a second part of the cover in a second moulding operation, the second moulding operation comprising forming a precursor for the electrical circuitry, and thereafter applying an electroconductive material to the precursor to form the electrical circuitry.

6. A process according to claim 5, wherein the integral connector structure is formed on the second part during the second moulding operation.

7. A process according to claim 5, wherein the first moulding operation comprises introducing a first plastics material into the first part of the mould.

8. A process according to claim 5, wherein electroconductive material is a metallic material.

9. A process according to claim 5, wherein a step of applying the electroconductive material comprises plating the electroconductive material onto the precursor.

10. A process according to claim 9, wherein the step of plating the electroconductive material consists of one or both selected from electroplating and electroless plating.

11. A process according to claim 9, wherein the second moulding operation comprises introducing a second plastics material into the mould, the second plastics material carrying a seeding substance to seed the plating of the electroconductive material onto the precursor, the seeding substance comprising metallic particles.

12. A process according to claim 1, wherein the step of incorporating the electrical circuitry into the cover comprises providing a substrate, forming a precursor for the electrical circuitry on the substrate, moulding the substrate to form the cover and then applying an electroconductive material to the precursor to form the electrical circuitry.

13. A process according to claim 12, wherein the step of applying the electroconductive material comprises plating the electroconductive material onto the precursor.

14. A process according to claim 13, wherein the step of plating the electroconductive material consists of one or both selected from electroplating and electroless plating.

15. A process according to claim 13, wherein the step of forming the precursor comprises applying a carrier material to the substrate, the carrier material carrying a seeding substance to seed the plating of the electroconductive material onto the precursor, the secondary substance comprising metallic particles.

16. A process according to claim 15, wherein the carrier material comprises an ink and the step of applying the carrier material to the substrate comprises printing the carrier material on the substrate.

17. A process according to claim 12, wherein the substrate comprises a plastics material and the step of moulding the substrate to form the cover comprises vacuum or press moulding the substrate.

18. A process according to claim 12, wherein the step of providing the connector structure on the cover comprises moulding the connector onto the cover after the substrate has been moulded to form the cover.

19. A process according to claim 1 comprising providing a flexible holding member in the connector structure to hold the electronic component in electrical communication with the electrical circuitry.

20. A process according to claim 19, wherein the flexible holding member comprises a resilient member.

21. A cover for an electronic device, the cover comprising an integral electrical circuitry, and an integral connector structure on the cover for connecting the electrical circuitry to an electronic component.

22. A cover according to claim 21, wherein the electrical circuitry is moulded on the cover.

23. A cover according to claim 22, formed of first and second integrally moulded parts, wherein the second moulded part comprises a precursor for the electrical circuitry.

24. A cover according to claim 23, wherein the second part comprises a precursor for the electrical circuitry, and a layer of an electrically conductive material providing said electrical circuitry.

25. A cover according to claim 25, wherein the electroconductive material comprises a plated metallic material.

26. A cover according to claim 21, wherein the cover is provided with a precursor for the electrical circuitry applied thereto, and an electroconductive material on the precursor.

27. A cover according to claim 27, wherein the precursor is printed onto the cover and comprises a carrier material carrying a sealing substance.

28. A cover arrangement according to claim 28, wherein the electroconductive material is plated onto the carrier material.

29. A cover according to claim 29, wherein the electroconductive material is a metallic material.

30. A cover according to claim 21, wherein the connection structure includes a holding member to hold the electronic component in electrical communication with the electrical circuitry.

31. A cover arrangement according to claim 31, wherein the flexible holding member comprises a resilient spring.

32. A cover arrangement according to claim 21, wherein the connector structure is formed on the cover by being moulded with the cover.
